(19) United States
(12) Patent Application Publication
(10) Pub. No.: US 2024/0402650 A1
(43) Pub. Date: Dec. 5, 2024

(54) WEARABLE DEVICE THAT REDUCES HEAT CONDUCTION FROM HEAT SOURCE TO HUMAN BODY

(71) Applicant: DIC Corporation, Tokyo (JP)

(72) Inventor: Kenichi Fujisaki, Saitama (JP)

(73) Assignee: DIC Corporation, Tokyo (JP)

(21) Appl. No.: 18/700,433

(22) PCT Filed: Oct. 13, 2022
(86) PCT No.: PCT/JP2022/038149

§ 371 Date: Apr. 11, 2024

(30) Foreign Application Priority Data
Oct. 25, 2021 (JP) 2021-174179

(51) Int. Cl. G04B 37/00

(52) U.S. Cl. CPC G04B 37/0008

(57) ABSTRACT

A wearable device includes: a housing configured to be worn on a human body and accommodating a heat source; and a heat insulator configured to reduce heat conduction from the heat source to the human body. The housing includes a wall that contacts the human body in a state that the housing is worn on the human body, and the heat insulator is disposed inside the housing at a position between the heat source and the wall of the housing.

### CROSS-REFERENCE TO RELATED APPLICATIONS

The present application claims priority from Japanese Patent Application No. 2021-174179, filed on Oct. 25, 2021, the contents of which are incorporated herein by reference.

### BACKGROUND

### Technical Field

The present invention relates to a wearable device, which is a small and light-weight electronic device to be worn on a human body.

### Description of Related Art

The use of wearable device is expected to spread worldwide in the near future. Some wearable devices have functions including a smartphone-like function for receiving e-mails and checking messages posted on SNS, etc., a function for recording exercises such as jogging or swimming, a function for recoding heart rate, pulse rate, sleeping hours, etc., for healthcare purposes, or a function for superposing a virtual image over the images of things in the real world to display information. Variations of the wearable device in practical use include, for example, watch-type, bracelet-type, earphone-type, wear-type, or ring-type wearable devices.

The wearable device is a device that a user wears for hours. Accordingly, the size and weight reduction is demanded more compared with information terminals, such as smart phones. The wearable device has a heat source, such as a processor, IC chips, or a battery, that is accommodated in the housing. Some heat generated by the heat source is conducted to the human body through the housing. In this case, when the heat conducted to the human body raises the temperature to a level exceeding the body temperature or exceeding, for example, 44° C., the user feels very uncomfortable.

For example, PTL 1 proposes a structure of a head mount display to be worn on the head of a user. The head mount display has a display unit (i.e., image display unit), which is a heat source, and frames extending rightward and leftward from the display unit (i.e., right-side and left-side extension portions). The frames are made of a heat conduction material that absorbs the heat of the display unit (image display unit).

In addition, PTL 2 proposes a structure of an electronic device that includes a control circuit and a battery accommodated in the housing. The electronic device has a heat storage member disposed between the control circuit and the battery. A gap (i.e., heat insulating air layer) is also formed between the control circuit and the battery.

### PATENT LITERATURE

PTL 1: Japanese Unexamined Patent Application Publication No. 2017-152955
PTL 2: International Publication No. 2017/081833

The head mount display proposed by PTL 1 transmits the heat generated in the display unit (i.e., the heat source) to the frames (right-side and left-side extension portions) having a high thermal conductivity in order to reduce the temperature increase in the display unit. The user, however, receives the heat conducted to the frames and may feel uncomfortable.

On the other hand, the electronic device proposed by PTL 2 is not a wearable device to be worn by a user, and accordingly the heat conduction to the user's body is not taken into consideration.

### SUMMARY

One or more embodiments of the present invention provide a wearable device that can reduce heat conduction from the heat source to a human body effectively so as not to cause the user to feel uncomfortable.

Accordingly, the first aspect provides a wearable device that is configured to be worn on a human body and includes: a housing comprising a wall that contacts the human body when the wearable device is worn; a heat source disposed inside the housing; and a heat insulating member (i.e., a heat insulator), disposed inside the housing between the heat source and the wall that contacts the human body, that reduces heat conduction from the heat source to the human body.

In the wearable device, an air layer may be formed between the heat source and the heat insulating member. In the wearable device, a thermal diffusion sheet may be disposed on a surface of the heat insulating member that is closest to the heat source than any other surface of the heat insulating member. Moreover, an air layer may be formed between the heat source and the thermal diffusion sheet.

The second aspect provides a wearable device that is configured to be worn on a human body and includes: a housing comprising a wall that contacts the human body when the wearable device is worn; a heat source disposed inside the housing; and a heat storage member, disposed inside the housing between the heat source and the wall that contacts the human body, that stores heat generated by the heat source.

In the wearable device, the heat storage member may be one of a heat storage foam member (or heat storage form) and a heat storage sheet that contain a phase change material that liquefies at a melting point or more and stores the heat. In this case, the phase change material preferably has a melting point of 37 to 44° C. and a freezing point of 32 to 40° C., and more preferably, a melting point of 40 to 44° C. and a freezing point of 37 to 40° C.

In the wearable device, an air layer may be formed between the heat source and the heat storage member. In the wearable device, a thermal diffusion sheet may be disposed on a surface of the heat storage member that is closest to the heat source than any other surface of the heat storage member. Moreover, an air layer may be formed between the heat source and the thermal diffusion sheet.

According to the first aspect, when the user wears and uses the wearable device on the user's body, the heat insulating member exhibits a heat insulating effect and reduces the conduction of some heat from the heat source to the user's body. As a result, the user does not feel uncomfortable even if the user wears the wearable device for hours.

In the case of the air layer being formed between the heat source and the heat insulating member, the air layer serves as a heat insulating layer. Accordingly, the heat conduction from the heat source to the user's body is further reduced due to the combined heat insulating effect of the air layer and the heat insulating member, which prevents the user from feeling uncomfortable. In the case of the thermal diffusion sheet being disposed on the surface of the heat insulating member facing the heat source, the thermal diffusion sheet releases some heat of the heat source inside the housing, which reduces the amount of heat conducted to the heat insulating member and thereby prevents the user from feeling uncomfortable. In this case, the air layer may be formed between the heat source and the thermal diffusion sheet. As a result, the heat conduction to the user's body is further reduced due to the combined effect of the heat insulation of the air layer and the heat insulating member and the heat diffusion of the thermal diffusion sheet.

According to the second aspect, when the user wears and uses the wearable device on the user's body, some heat of the heat source is stored in the heat storage member (i.e., heat storage foam or heat storage sheet), which reduces the heat conduction to the user's body. As a result, the user does not feel uncomfortable even if the user wears the wearable device for hours.

In addition, the heat storage member operates as a cooling device by storing (absorbing) some heat of the heat source, which reduces the temperature increase inside the housing and thermally protects electronic components of the heat source. This improves the durability of the electronic components.

The phase change material to be used for the heat storage member, which is the heat storage foam member or the heat storage sheet, has a melting point of 37 to 44° C. and a freezing point of 32 to 40° C. In this case, the phase change material melts and stores heat at a temperature of 37 to 44° C., which is higher than a surface temperature of the user's body (for example, 32 to 33° C.). As a result, the heat that the user receives from the wearable device is prevented from exceeding 44° C., which is a limiting temperature, in other words, the lowest temperature at which the user feels uncomfortable. When the user does not use the wearable device and takes off the wearable device from the body, the temperature of the wearable device drops to the freezing point of 32 to 40° C. or lower. As a result, the phase change material solidifies (i.e., changes the phase from liquid to solid) and thereby releases the heat stored. The phase change material returns to the initial state (the state before storing heat).

In the second aspect, the air layer is also formed between the heat source and the heat storage member so as to serve as a heat insulating layer as is the case for the first aspect. The heat conduction from the heat source to the user's body is further reduced due to the combined effect of the heat insulation of the air layer and the heat storage of the heat storage member, thereby preventing the user from feeling uncomfortable. The thermal diffusion sheet may be disposed on the surface of the heat storage member, the surface facing the heat source, which releases some heat of the heat source through the thermal diffusion sheet inside the housing and thereby reduces the amount of heat conducted to the heat storage member, which prevents the user from feeling uncomfortable. In this case, the air layer may be formed between the heat source and the thermal diffusion sheet, which further reduces the heat conduction to the user's body due to the combined effect of the heat insulation of the air layer, the heat diffusion of the thermal diffusion sheet, and the heat storage of the heat storage member.

### BRIEF DESCRIPTION OF DRAWINGS

FIG. 1 is a perspective view illustrating part of a smart watch that is one form of a wearable device according to one or more embodiments of the present invention.

FIG. 2 is a longitudinal section schematically illustrating an internal structure of a smart watch according to Embodiment 1 of a first aspect of the present invention.

FIG. 3 is a longitudinal section schematically illustrating an internal structure of a smart watch according to Embodiment 2 of the first aspect.

FIG. 4 is a longitudinal section schematically illustrating an internal structure of a smart watch according to Embodiment 3 of the first aspect.

FIG. 5 is a longitudinal section schematically illustrating an internal structure of a smart watch according to Embodiment 4 of the first aspect.

FIG. 6 is a longitudinal section schematically illustrating an internal structure of a smart watch according to Embodiment 1 of a second aspect of the present invention.

FIG. 7 is a longitudinal section schematically illustrating an internal structure of a smart watch according to Embodiment 2 of the second aspect.

FIG. 8 is a longitudinal section schematically illustrating an internal structure of a smart watch according to Embodiment 3 of the second aspect.

FIG. 9 is a longitudinal section schematically illustrating an internal structure of a smart watch according to Embodiment 4 of the second aspect.

FIG. 10 is a graph depicting relationship between temperature and elapsed time, the graph being obtained from heat cycle tests performed on a heat storage foam member, a heat insulating member, and a stainless steel plate.

### DETAILED DESCRIPTION OF EMBODIMENTS

Embodiments of the first aspect will be described with reference to the drawings.

### [First Aspect]

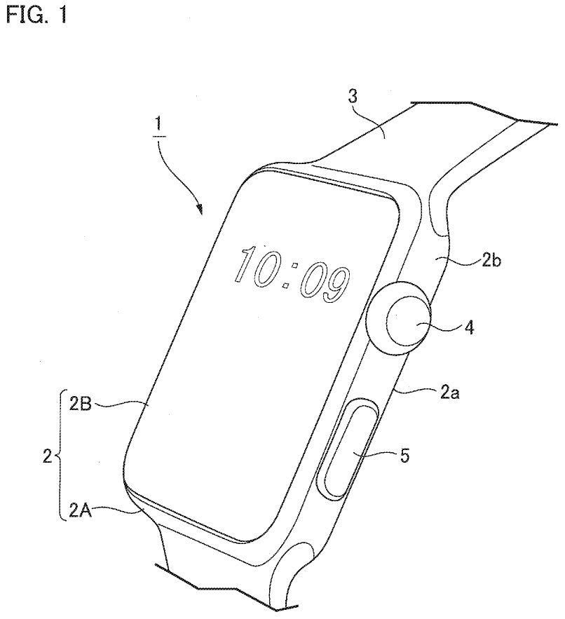

A general structure of a smart watch, which is one form of a wearable device according to one or more embodiments of the present invention, will be described first with reference to FIG. 1.

FIG. 1 is a perspective view illustrating part of the smart watch. The smart watch 1 illustrated has multiple functions including a smartphone-like function for receiving e-mails and checking messages posted on SNS, a function for recording exercises such as jogging or swimming, or a function for recoding heart rate, pulse rate, sleeping hours, etc., for healthcare purposes. The smart watch includes a housing 2 and a band 3 extending from opposite ends of the housing 2.

The housing 2 is formed of a casing 2A and a cover 2B. The casing 2A is shaped like a rectangular container with an opening at the top, and the cover 2B is a transparent cover that covers the opening of the casing 2A. The casing 2A and the cover 2B define an enclosed space. For example, the casing 2A is made of stainless steel (SUS), aluminum, or titanium, and the cover 2B is made of a transparent glass or a transparent resin.

The casing 2A, which constitutes a part of the housing 2, includes a bottom wall 2a and side walls 2b. When a user wears this smart watch 1, the bottom wall 2a comes into contact with part of the user's body (more specifically, the user's wrist). The side walls 2b rise vertically from four sides of the bottom wall 2a. Push-buttons 4 and 5 for switching operation modes or the like are provided on a side wall 2b.

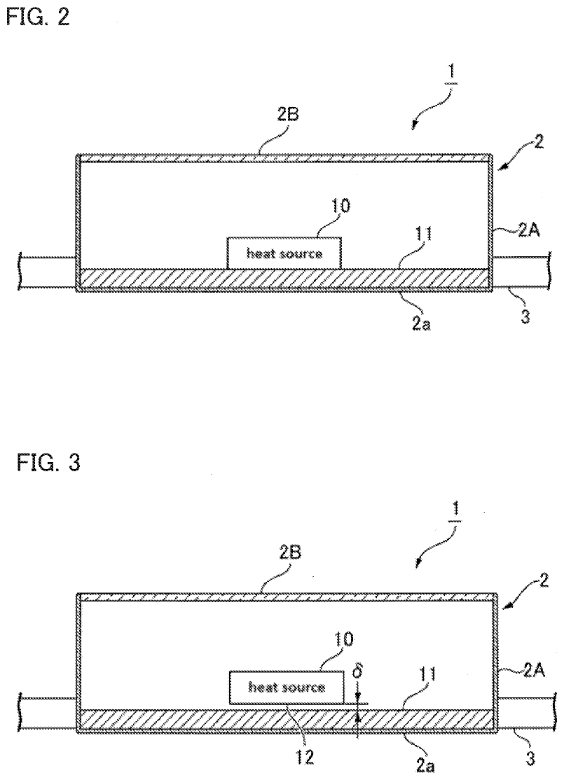

The housing 2 of the smart watch 1 has a heat source 10 (see FIG. 2), such as a processor, an IC chip, or a battery, and some heat of the heat source 10 is conducted to the user's body (wrist) through part of the housing 2 (more specifically, the bottom wall 2a of the casing 2A). In this case, as described above, when the heat conducted to the user's body (wrist) raises the temperature to a level exceeding the body temperature or exceeding, for example, 44° C., the user feels very uncomfortable.

Accordingly, a heat insulating structure is provided inside the housing 2 in order to prevent or reduce heat conduction from the heat source 10 to the user's body (wrist). The following describes example forms of the heat insulating structure.

### Embodiment 1

FIG. 2 is a longitudinal section schematically illustrating an internal structure of a smart watch according to Embodiment 1 of a first aspect of the present invention. As illustrated, the housing 2 accommodates the heat source 10, such as a processor, IC chips, or a battery, at the center thereof. In the present embodiment, the housing 2 (casing 2A) also accommodates a tabular-shaped (flat plate) heat insulating member 11 disposed at a position between the heat source 10 and the bottom wall 2a that comes into contact with the user's wrist. The heat insulating member 11 reduces the heat conduction from the heat source 10 to the user's wrist. In this case, the heat insulating member 11 is disposed so as to cover the entire inside surface of the bottom wall 2a of the housing 2 (casing 2A). For example, the heat insulating member 11 is made of a foamed plastic, such as rigid polyurethane foam, rigid polystyrene foam, phenolic foam, or acrylic form.

When the user wears the smart watch 1 having the heat insulating structure on the wrist, the heat insulating member 11 exhibits a heat insulating effect and reduces the heat conduction from the heat source 10 to the user's wrist. As a result, the user does not feel uncomfortable at the wrist even if the user wears the smart watch 1 for hours.

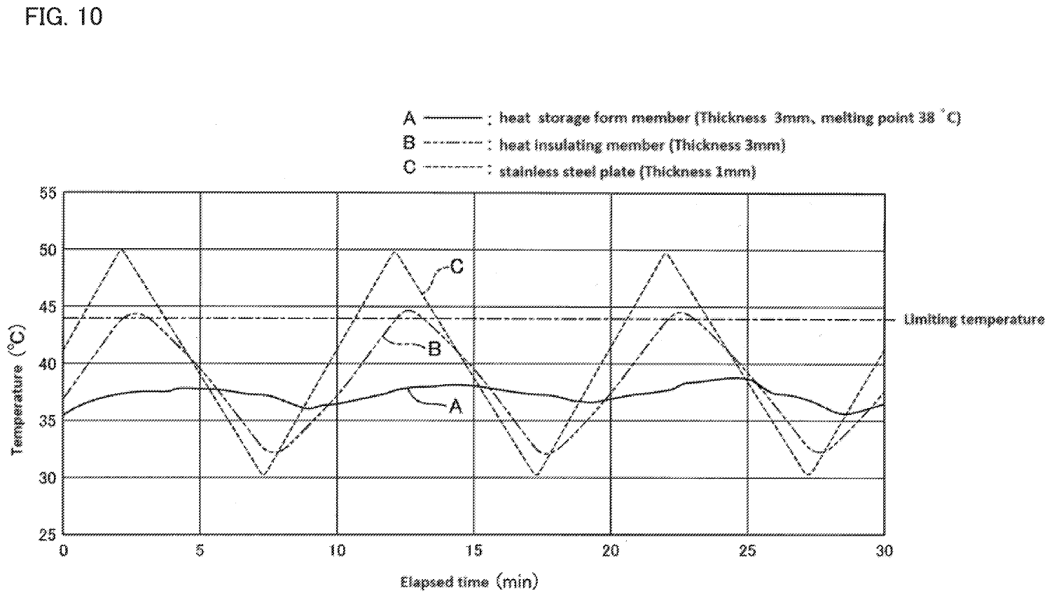

FIG. 10 depicts results of heat cycle tests performed on the heat insulating member (3 mm thick) and a stainless steel plate (1 mm thick). In FIG. 10, the horizontal axis represents elapsed time (in minute), and the vertical axis represents temperature (in ° C.). The heat cycle tests were performed using a Peltier device by cyclically increasing and decreasing the temperature in the range between 30° C. and 50° C. at predetermined time intervals. Meanwhile, the surface temperatures of the heat insulating member and the stainless steel plate were measured.

As is clear from the test results in FIG. 10, the temperature of the heat insulating member is held in the range of 32.5 to 44° C. as indicated by dash-dot-dot line B in FIG. 10 while the temperature of the stainless steel plate rises and drops cyclically in the range of 30 to 50° C.

Accordingly, in the case where the casing 2A of the housing 2 is made of the stainless steel (SUS) and the heat insulating structure of the present embodiment is not provided, the user is exposed to heat at 50° C., which exceeds the limiting temperature of 44° C., and the user feels very uncomfortable at the wrist.

On the other hand, the smart watch 1 of the present embodiment has the heat insulating structure in which the heat insulating member 11 is disposed inside the housing 2 at a position between the heat source 10 and the bottom wall 2a of the casing 2A. As is clear from the results in FIG. 10, the smart watch 1 can reduce the amount of heat conducted from the heat source 10 to the user's wrist through the heat insulating member 11 and the bottom wall 2a of the casing 2A. Accordingly, the user feels heat at a temperature below the limiting temperature of 44° C., and the user does not feel very uncomfortable.

In addition, the heat insulating structure of the present embodiment can be implemented simply by incorporating the heat insulating member 11 between the heat source 10 and the bottom wall 2a inside the housing 2, which can improve efficiency in assembling the smart watch 1.

### Embodiment 2

Embodiment 2 of the first aspect will be described with reference to FIG. 3.

FIG. 3 is a longitudinal section schematically illustrating an internal structure of a smart watch according to Embodiment 2 of the first aspect. In FIG. 3, the same elements as those illustrated in FIG. 2 are denoted by the same reference signs, and duplicated descriptions will be omitted.

The present embodiment is different from Embodiment 1 in that the heat insulating structure has a gap 6 provided between the heat source 10 and the heat insulating member 11. The gap 6 is an air layer 12. Other configurations are the same as those of Embodiment 1.

In the present embodiment, the air layer 12 formed between the heat source 10 and the heat insulating member 11 serves as a heat insulating layer. The heat conduction from the heat source 10 to the user's wrist is further reduced due to the combined heat insulating effect of the air layer 12 and the heat insulating member 11. As a result, the user does not feel uncomfortable.

### Embodiment 3

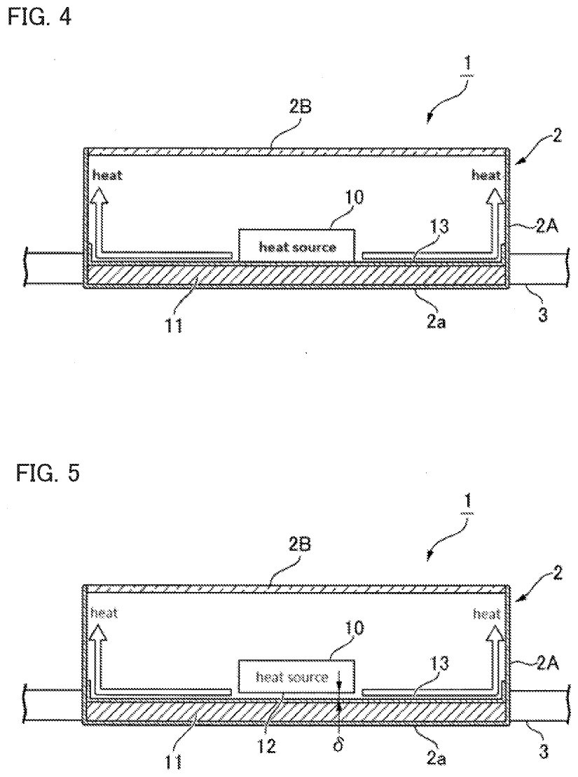

Embodiment 3 of the first aspect will be described with reference to FIG. 4.

FIG. 4 is a longitudinal section schematically illustrating an internal structure of the smart watch according to Embodiment 3 of the first aspect. In FIG. 4, the same elements as those illustrated in FIG. 2 are denoted by the same reference signs, and duplicated descriptions will be omitted.

The present embodiment is different from Embodiment 1 in that the heat insulating structure has a thermal diffusion sheet 13 disposed on a surface (i.e., top surface) of the heat insulating member 11 facing the heat source 10. Other configurations are the same as those of Embodiment 1. The thermal diffusion sheet 13 may be made of a graphite film, an aluminum foil, or a composite film of these.

In the present embodiment, the thermal diffusion sheet 13 disposed on the surface of the heat insulating member 11 facing the heat source 10 diffuses some heat of the heat source 10 within the housing 2, which reduces the amount of heat conducted to the heat insulating member 11. This lowers the temperature that the user feels at the wrist, which prevents the user from feeling uncomfortable.

### Embodiment 4

Embodiment 4 of the first aspect will be described with reference to FIG. 5.

FIG. 5 is a longitudinal section schematically illustrating an internal structure of a smart watch according to Embodiment 4 of the first aspect. In FIG. 5 the same elements as those illustrated in FIGS. 2 to 4 are denoted by the same reference signs, and duplicated descriptions will be omitted.

The present embodiment is different from Embodiment 3 in that the heat insulating structure has the air layer 12 provided between the heat source 10 and the thermal diffusion sheet 13. Other configurations are the same as those of Embodiment 3.

In the present embodiment, the air layer 12 formed between the heat source 10 and the thermal diffusion sheet 13 further reduces the heat conduction to the user's body due to the combined heat insulating effect of the air layer 12 and the heat insulating member 11 acting together with the heat diffusion of the thermal diffusion sheet 13.

### [Second Aspect]

Next, a wearable device according to a second aspect of the present invention will be described with reference to the smart watch 1 of FIG. 1 as an example, as is the case for the first aspect. Accordingly, duplicated descriptions of the structure of the smart watch 1 will be omitted, and the description will focus on an example form of the heat storage structure of the smart watch 1.

### Embodiment 1

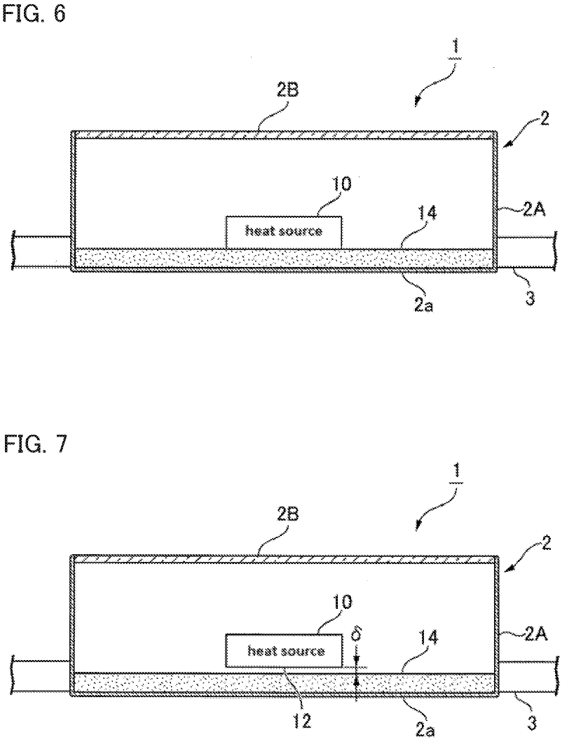

Embodiment 1 of the second aspect will be described with reference to FIG. 6.

FIG. 6 is a longitudinal section schematically illustrating an internal structure of a smart watch according to Embodiment 1 of the second aspect. In FIG. 6, the same elements as those illustrated in FIG. 2 are denoted by the same reference signs, and duplicated descriptions will be omitted.

In the present embodiment, a heat storage foam member 14 is disposed inside the housing 2 at a position between the heat source 10 and the bottom wall 2a of the housing 2 that comes into contact with the human body (the user's wrist). The heat storage foam member 14 serves as a heat storage member for storing heat generated by the heat source 10. Other configurations are the same as those of the smart watch 1 of Embodiment 1 of the first aspect (see FIG. 2).

The heat storage foam member 14 contains a phase change material that liquefies at a melting point or more and thereby stores heat. For example, the heat storage foam member 14 can be obtained as follows. A binder to be used for foaming machine is prepared first by mixing heat storage particles in an aqueous emulsion of acrylic polymer. Subsequently, the binder is applied on a PET film and then shaped and hardened through heat treatment using a dryer. For example, polyurethane foam, polyethylene foam, melamine foam, or acrylic foam can be used for the base foam. For example, polyurethane polymer, polyolefin-based polymers, vinyl chloride-based polymers, polyamide-based polymers, or acrylic polymers can be used for the binder polymer. For the phase change material, a fatty acid ester, such as methyl decanoate and ethyl decanoate, or an alkane (paraffin), such as Decane, Undecane, and Dodecane, is used. The phase change material absorbs heat of fusion (latent heat) during the phase change from solid to liquid, while the phase change material releases heat of solidification (latent heat) during the phase change from liquid to solid. The phase change material used in the present embodiment has a melting point of 37 to 39° C. and a freezing point of 33 to 35° C.

Although the heat storage foam member 14 is used as the heat storage member in the present embodiment, the heat storage member may be a heat storage sheet. The heat storage sheet can be obtained by dispersing granular phase change material in a resin such as vinyl chloride and by forming a thick film.

When the user wears the smart watch 1 having the heat storage structure on the wrist and the heat source 10 generates heat, the temperature inside the housing 2 may exceed the melting point of 37 to 39° C. of the phase change material contained in the heat storage foam member 14. In this case, the phase change material melts and liquefies, and the heat storage foam member 14 thereby absorbs and stores the heat of fusion (latent heat) from the surroundings. Accordingly, the heat storage foam member 14, which operates as a cooling device, stores heat in the housing 2 and reduces the temperature increase, thereby reducing the amount of heat conducted to the user's wrist through the bottom wall 2a of the housing 2 (casing 2A). As a result, the user does not feel uncomfortable even if the user wears the smart watch 1 for hours.

FIG. 10 depicts results of heat cycle tests performed on the heat storage foam member (3 mm thick, melting point of 38° C.) and a stainless steel plate (1 mm thick). The heat cycle tests were performed using a Peltier device by cyclically increasing and decreasing the temperature in the range between 30° C. and 50° C. at predetermined time intervals. Meanwhile, the surface temperatures of the heat storage foam member and the stainless steel plate were measured.

As is clear from the test results in FIG. 10, the temperature of the stainless steel plate rises and drops cyclically in the range of 30 to 50° C. as indicated by dashed line C, while the temperature of the heat storage foam member fluctuates with a small amplitude in the vicinity of the melting point of 38° C. of the phase change material as indicated by solid line A. The highest temperature of the heat storage foam member is held lower than the highest temperature of the heat insulating member as indicated by dash-dot-dot lime B in FIG. 10.

Accordingly, in the case where the casing 2A of the housing 2 is made of the stainless steel (SUS) and the heat storage structure of the present embodiment is not provided, the user is exposed to heat at 50° C., which exceeds the limiting temperature of 44° C., and the user feels very uncomfortable at the wrist.

On the other hand, the smart watch 1 of the present embodiment has the heat storage structure in which the heat storage foam member 14 is disposed between the heat source 10 and the bottom wall 2a of the casing 2A inside the housing 2. As is clear from the results in FIG. 10, the smart watch 1 can reduce the amount of heat conducted from the heat source 10 to the user's wrist through the heat storage foam member 14 and the bottom wall 2a of the casing 2A. Accordingly, the user feels heat at a temperature below the limiting temperature of 44° C., which does not cause the user to feel very uncomfortable.

When the user does not use the smart watch 1 and takes off the smart watch 1 from the wrist, the temperature of the smart watch 1 drops to the freezing point of 33 to 35° C. or lower. As a result, the phase change material contained in the heat storage foam member 14 solidifies (i.e., changes the phase from liquid to solid) and thereby releases the heat stored. The heat storage foam member 14 returns to the initial state (the state before storing heat). Even if the user wears the smart watch 1 on the wrist, the user's body has a surface temperature of about 32 to 33° C. and may cause the temperature of the phase change material to drop to the freezing point or lower when the smart watch 1 produces less heat. Also in this case, the phase change material solidifies (i.e., changes the phase from liquid to solid) and thereby releases the heat stored. The heat storage foam member 14 returns to the initial state (the state before storing heat). Note that the heat of fusion and the heat of solidification are both latent and accordingly the temperature of the heat storage foam member 14 does not change noticeably by storing or releasing heat.

In addition, in the present embodiment, the heat storage foam member 14 operates as a cooling device and stores heat and thereby reduces the temperature increase inside the housing 2, as described above. This prevents heat deterioration of the components of the heat source 10, such as a processor, IC chips, or a battery, and thereby improves the durability of the components.

Moreover, the heat storage structure of the present embodiment can be implemented simply by incorporating the heat storage foam member 14 between the heat source 10 and the bottom wall 2a of the casing 2A inside the housing 2, which can improve efficiency in assembling the smart watch 1.

### Embodiment 2

Embodiment 2 of the second aspect will be described with reference to FIG. 7.

FIG. 7 is a longitudinal section schematically illustrating an internal structure of a smart watch according to Embodiment 2 of the second aspect. In FIG. 7, the same elements as those illustrated in FIG. 6 are denoted by the same reference signs, and duplicated descriptions will be omitted.

The present embodiment is different from Embodiment 1 in that the heat storage structure has a gap 6 provided between the heat source 10 and the heat storage foam member 14. The gap 6 is the air layer 12. Other configurations are the same as those of Embodiment 1.

In the present embodiment, the air layer 12 formed between the heat source 10 and the heat storage foam member 14 serves as a heat insulating layer. The heat conduction from the heat source 10 to the user's wrist is further reduced due to the combined effect of the heat insulation of the air layer 12 and the heat storage of the heat storage foam member 14, which prevents the user from feeling uncomfortable.

### Embodiment 3

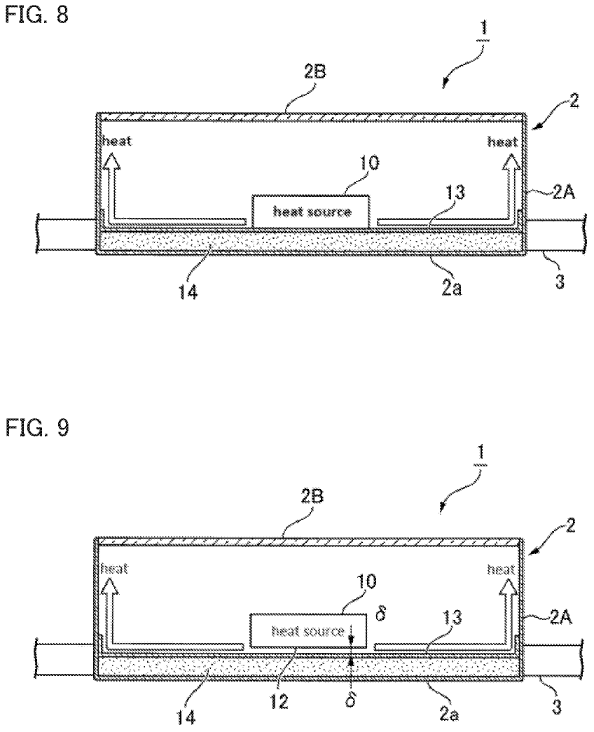

Embodiment 3 of the second aspect will be described with reference to FIG. 8.

FIG. 8 is a longitudinal section schematically illustrating an internal structure of a smart watch according to Embodiment 3 of the second aspect. In FIG. 8, the same elements as those illustrated in FIG. 6 are denoted by the same reference signs, and duplicated descriptions will be omitted.

The present embodiment is different from Embodiment 1 (FIG. 6) in that the heat storage structure has the thermal diffusion sheet 13 disposed on a surface (i.e., top surface) of the heat storage foam member 14, the surface facing the heat source 10. Other configurations are the same as those of Embodiment 1. The thermal diffusion sheet 13 may be made of a graphite film, an aluminum foil, or a composite film of these.

In the present embodiment, the thermal diffusion sheet 13 is disposed on the surface (i.e., top surface) of the heat storage foam member 14, the surface facing the heat source 10, which releases some heat of the heat source 10 inside the housing 2 and thereby reduces the amount of heat conducted to the heat storage foam member 14. The thermal diffusion sheet 13 diffuses the heat of the heat source 10, and some of the heat is absorbed by the heat storage foam member 14, which prevents local heating of the smart watch 1. This lowers the temperature that the user feels at the wrist, which prevents the user from feeling uncomfortable.

### Embodiment 4

Embodiment 4 of the second aspect will be described with reference to FIG. 9.

FIG. 9 is a longitudinal section schematically illustrating an internal structure of a smart watch according to Embodiment 4 of the second aspect. In FIG. 9, the same elements as those illustrated in FIG. 8 are denoted by the same reference signs, and duplicated descriptions will be omitted.

The present embodiment is different from Embodiment 3 in that the heat storage structure has the air layer 12 provided between the heat source 10 and the thermal diffusion sheet 13. Other configurations are the same as those of Embodiment 3.

In the present embodiment, the air layer 12 is formed between the heat source 10 and the thermal diffusion sheet 13, which further reduces the heat conduction to the user's body due to the combined effect of the heat insulation of the air layer 12, the heat diffusion of the thermal diffusion sheet 13, and the heat storage of the heat storage foam member 14. Although the heat storage foam member 14 is used as the heat storage member in the descriptions of Embodiments 1 to 4 of the second aspect, a heat storage sheet may be used to serve as the heat storage member in the same manner as described above, which provides similar advantageous effects.

The tendency of reducing the size and thickness of the wearable device (including the smart watches described in the above embodiments by way of example) as well as reducing the inside space thereof creates a demand for reducing the size of components mounted therein including the heat insulating member and the heat storage foam member (or the heat storage sheet). Accordingly, a thin heat insulating member can be used in one or more embodiments of the present invention. The thickness of the heat insulating member is such that the upper limit is preferably 5 mm or less, 4 mm or less, or 3.5 mm or less, whereas the lower limit is preferably 0.01 mm or more, 0.1 mm or more, or 0.5 mm or more.

Regarding the heat insulating member, the smaller the thickness, the smaller the heat insulating effect.

Provided that the thickness is the same, the heat storage foam member and the heat storage sheet, which have both heat insulating and storage functions, tend to exhibit a better heat insulating effect required for the wearable device, compared with the heat insulating member (such as a formed plastic member or an air layer), which has only the heat insulating function. Accordingly, the heat storage foam member and the heat storage sheet are less likely to give an uncomfortable feeling to the human body. This can be also seen from the results of the heat cycle tests in FIG. 10.

Accordingly, in the case of the wearable device that requires to use a thin heat insulating member, the heat storage member, such as the heat storage foam member or the heat storage sheet, can be used rather than the heat insulating member, such as the formed plastic member or the air layer, because the heat storage member reduces the likelihood of giving an uncomfortable feeling to the human body even if the heat storage member is thin.

In the above embodiments, the heat cycle tests were performed on the heat storage foam member and the heat insulating member both having a thickness of 3 mm. In view of the results depicted in FIG. 10, the wearable device is likely to exhibit optimal heat insulating characteristics even if the thickness of the heat storage foam member or the heat storage sheet is reduced to less than 3 mm.

Accordingly, when the heat storage member, such as the heat storage foam member and the heat storage sheet, is used for the heat insulating purpose, the upper limit of the thickness is preferably 3 mm or less, 2 mm or less, or 1.5 mm or less, whereas the lower limit of the thickness is preferably 0.01 mm or more, 0.05 mm or more, or 0.1 mm or more.

The smart watch, which is one form of the wearable device, has been described as an application example of one or more embodiments of the present invention. The present invention, however, can be applied to any suitable wearable device, such as smart glasses, a smart earphone, a smart cap, a smart ring, or smart wear, for example.

The application of the present invention is not limited to the embodiments described above. Various alterations and modifications can be made within the technical ideas disclosed in the claims as well as in the specification and drawings.

### REFERENCE SIGNS LIST

1 smart watch (wearable device)
2 housing
2A casing
2a bottom wall of casing
2b side wall of casing
2B cover
3 band
4, 5 push-button
10 heat source
11 heat insulating member
12 air layer
13 thermal diffusion sheet
14 heat storage foam member (heat storage member)
6 gap

1. A wearable device configured to be worn on a human body, comprising:
a housing comprising a wall that contacts the human body when the wearable device is worn;
a heat source disposed inside the housing; and
a heat insulator, disposed inside the housing between the heat source and the wall that contacts the human body, that reduces heat conduction from the heat source to the human body.

2. The wearable device according to claim 1, wherein
an air layer is formed between the heat source and the heat insulator.

3. The wearable device according to claim 1, wherein
a thermal diffusion sheet is disposed on a surface of the heat insulator that is closest to the heat source than any other surface of the heat insulator.

4. The wearable device according to claim 3, wherein
an air layer is formed between the heat source and the thermal diffusion sheet.

5. A wearable device configured to be worn on a human body, comprising:
a housing comprising a wall that contacts the human body when the wearable device is worn;
a heat source disposed inside the housing; and
a heat storage member, disposed inside the housing between the heat source and the wall that contacts the human body, that stores heat generated by the heat source.

6. The wearable device according to claim 5, wherein
the heat storage member is one of a heat storage foam and a heat storage sheet that contain a phase change material that liquefies at a melting point or more and stores the heat.

7. The wearable device according to claim 6, wherein
the phase change material has a melting point of 37 to 44° C. and a freezing point of 32 to 40° C.

8. The wearable device according to claim 5, wherein
an air layer is formed between the heat source and the heat storage member.

9. The wearable device according to claim 5, wherein
a thermal diffusion sheet is disposed on a surface of the heat storage member that is closest to the heat source than any other surface of the heat storage member.

10. The wearable device according to claim 9, wherein
an air layer is formed between the heat source and the thermal diffusion sheet.
